(19) United States
(12) Patent Application Publication
(10) Pub. No.: US 2026/0113862 A1
(43) Pub. Date: Apr. 23, 2026

(54) SERVER AND GUIDING DEVICE THEREOF

(71) Applicant: Wistron Corporation, New Taipei City (TW)

(72) Inventor: Hao CHIN, New Taipei City (TW)

(21) Appl. No.: 19/004,810

(22) Filed: Dec. 30, 2024

(30) Foreign Application Priority Data
Oct. 23, 2024 (TW) 113140413

(51) Int. Cl. H05K 7/14

(52) U.S. Cl. CPC H05K 7/1489; H05K 7/1409

(57) ABSTRACT

A server includes a server housing and a guiding device. The server housing includes an insertion portion. The guiding device includes a base and an unlocking member. The base includes a guiding track and a shaft. The base is fixed to the server housing, and the guiding track is adjacent to the insertion portion. The shaft has a fixed portion, the fixed portion has a latch position and a withdrawn position, and the latch position is closer to the insertion portion than the withdrawn position. The unlocking member includes a main body, a connecting portion, an abutting portion, and an operating portion. The unlocking member is movably arranged on the base through the connecting portion to have the initial position and the unlocking position. The abutting portion makes the fixed portion at the withdrawn position when the unlocking member is at the unlocking position.

### CROSS-REFERENCE TO RELATED APPLICATION

This non-provisional application claims priority under 35 U.S.C. § 119(a) to Patent Application No. 113140413 filed in Taiwan, R.O.C. on Oct. 23, 2024, the entire contents of which are hereby incorporated by reference.

### BACKGROUND

### Technical Field

This application relates to a server, and especially, to a server having a plug-in module positioned in a server housing.

### Related Art

With the development of science and technologies, there is a growing demand for cloud computing devices, which leads to a huge increase in the demand for servers. In recent years, some users have gradually increased their requirements for server computing performance. To improve server computing performance, these users usually install expansion modules to enhance server computing capabilities. Some servers are expanded by inserting an expansion module from outside a server housing for use. However, when intending to withdraw the expansion module, the users need to remove a part of the housing to expose the expansion module to withdraw the expansion module from the housing. In addition, when withdrawing the expansion module, operators need to push the expansion module out of the housing by touching the expansion module with a hand. If the operators apply a force at an incorrect angle or apply an incorrect force, the expansion module is damaged.

### SUMMARY

In some embodiments, a server is provided. The server includes a server housing and a guiding device. The server housing includes an insertion portion. The guiding device includes a base and an unlocking member. The base includes a guiding track and a shaft. The base is fixed to the server housing, and the guiding track is adjacent to the insertion portion. The shaft has a fixed portion, the fixed portion has a latch position and a withdrawn position, and the latch position is closer to the insertion portion than the withdrawn position. The unlocking member includes a main body, a connecting portion, an abutting portion, and an operating portion. The connecting portion, the abutting portion, and the operating portion are connected to the main body. The unlocking member is movably arranged on the base through the connecting portion to have an initial position, an unlocking position, and a removal position. The operating portion is moved to selectively position the unlocking member at the initial position or the unlocking position. The abutting portion makes the fixed portion at the withdrawn position when the unlocking member is at the unlocking position.

In conclusion, according to some embodiments, in the server, when the plug-in module is to be installed on the server housing, the plug-in module may be inserted into the guiding track and withdrawn from the insertion portion. The guiding track may limit the plug-in module in a direction perpendicular to the guiding axis, so that the plug-in module may enter the insertion portion based on the insertion axis. When the plug-in module is at the insertion portion, the fixed portion of the shaft is at the latch position to limit the plug-in module in a direction of the insertion axis. The unlocking member is moved from the initial position to the unlocking position, and the abutting portion may move the fixed portion to the withdrawn position to release the limit of the plug-in module on the insertion axis. In response to the unlocking member being moved from the unlocking position to the removal position, the abutting portion may withdraw the plug-in module from the insertion portion. In response to the unlocking member being moved from the removal position to the initial position, the abutting portion may leave the guiding track, so that the plug-in module may re-enter the insertion portion. Therefore, users may withdraw the plug-in module from the server housing by operating the guiding device without touching the plug-in module. In this way, the server can prevent operators from inserting/plugging the plug-in module into/from the server housing with an incorrect force and at an incorrect angle.

### BRIEF DESCRIPTION OF THE DRAWINGS

FIG. 1A is a schematic three-dimensional diagram of a server according to some embodiments of the present invention;

FIG. 1B is a three-dimensional view of a guiding device in the embodiment of FIG. 1A;

FIG. 1C is a three-dimensional exploded view of a guiding device in the embodiment of FIG. 1A;

FIG. 2 is a partial side view of the server in FIG. 1A, showing sides of a guiding device and a server housing;

FIG. 3 is a top view of a guiding device without showing an unlocking member according to some embodiments of the present invention;

FIG. 4 is a partial cross-sectional view of the server in FIG. 1A at a cross-sectional position of a cross-sectional line 4-4, showing a plug-in module being inserted into an insertion portion;

FIG. 5 is a partial cross-sectional view from the same angle as FIG. 4, showing a state of the plug-in module being completely at the insertion portion;

FIG. 6 is an enlarged partial three-dimensional view of a region 6 in FIG. 5;

FIG. 7 is a partial cross-sectional view from the same angle as FIG. 4, showing a plug-in module being at an insertion portion and an unlocking member being at an unlocking position;

FIG. 8 is an enlarged partial three-dimensional view of a region 8 in FIG. 7;

FIG. 9 is a partial cross-sectional view from the same angle as FIG. 4, showing a plug-in module being away from an insertion portion and an unlocking member being at a removal position;

FIG. 10 is a partial cross-sectional view from the same angle as FIG. 4, showing a plug-in module being away from an insertion portion and an unlocking member being de-moved;

FIG. 11 is a partial side view of a server according to some embodiments of the present invention, showing a guiding portion being an arc-shaped guiding member; and

FIG. 12 is another schematic diagram of a guiding device according to some embodiments of the present invention.

### DETAILED DESCRIPTION

The following describes various embodiments in detail. However, the embodiments are merely used as examples for description, and do not limit the protection scope of the present invention. In addition, some components are omitted from the drawings in the embodiments, to clearly show the technical features of the present invention. In all the drawings, the same reference numerals are used to represent the same or similar components.

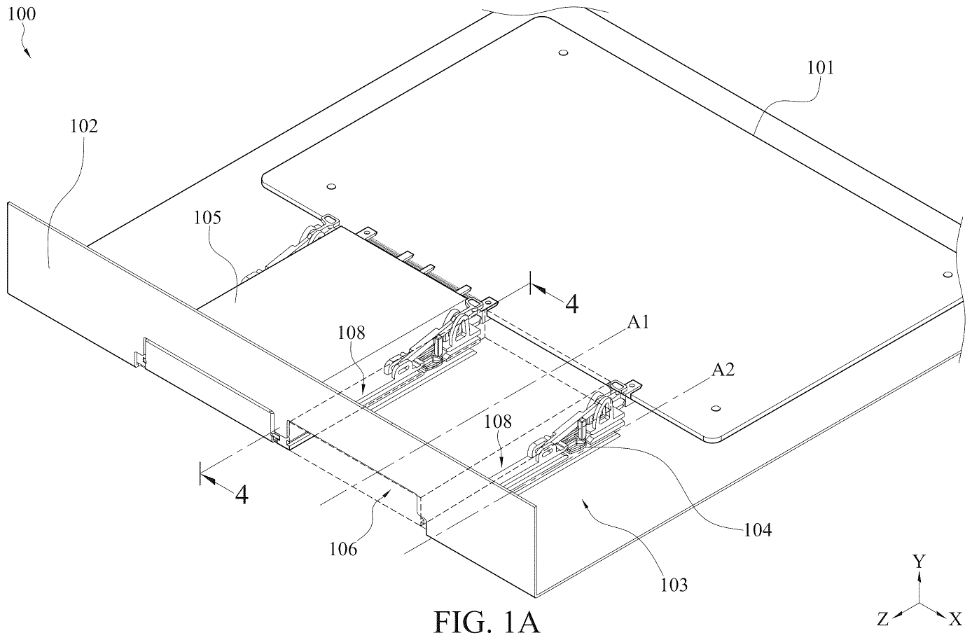

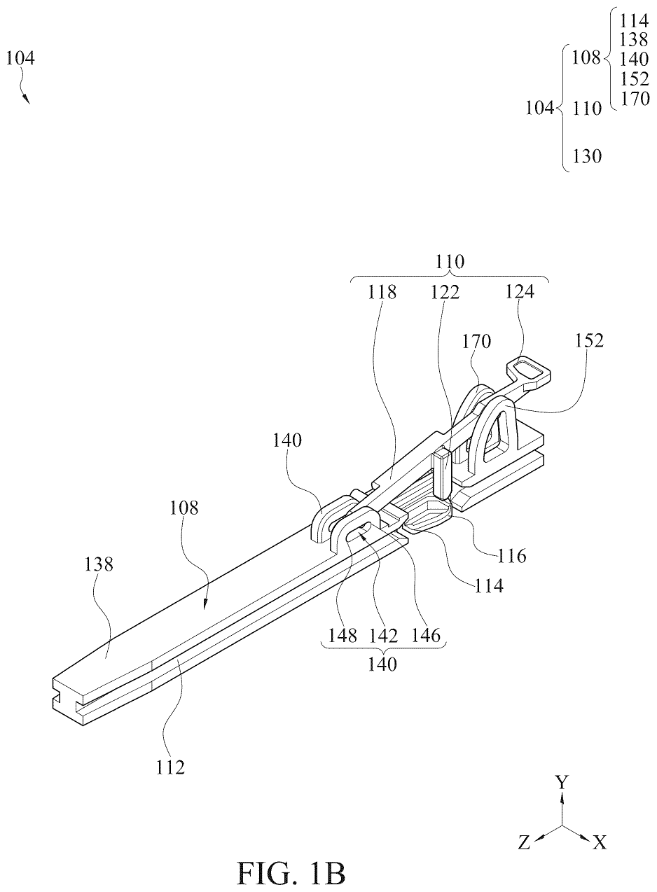

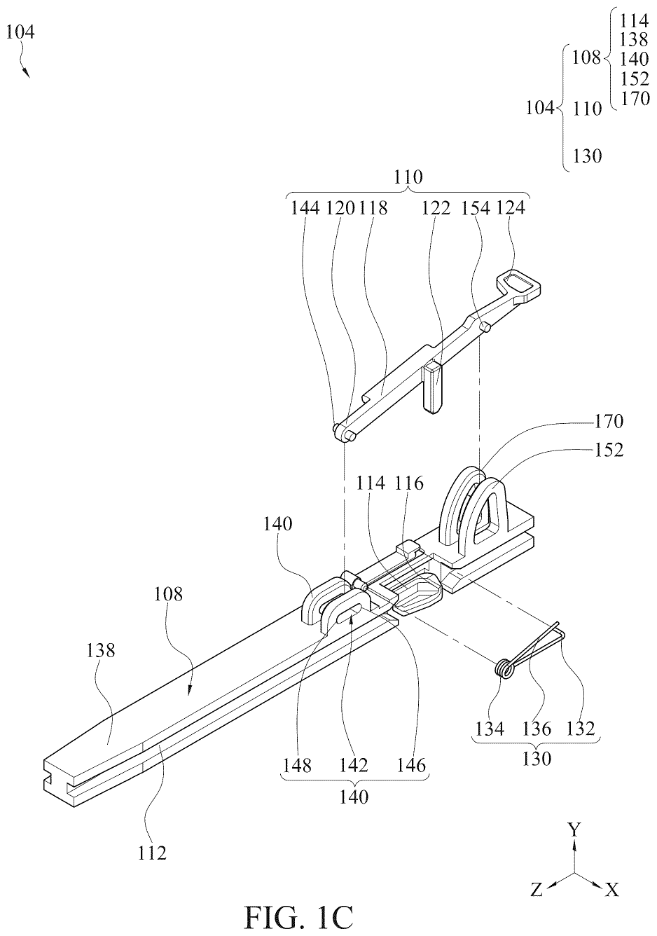

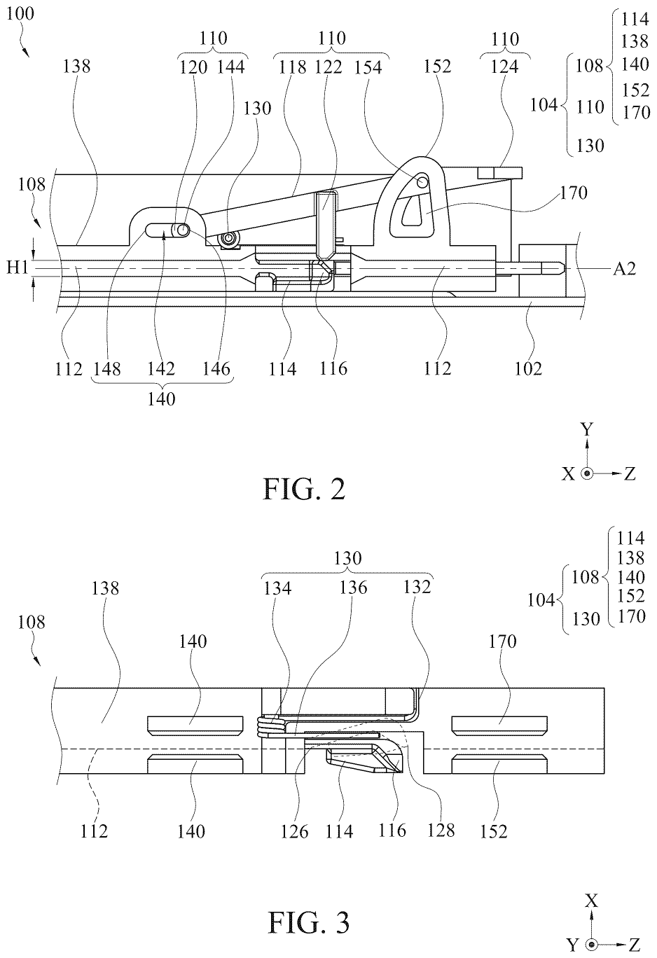

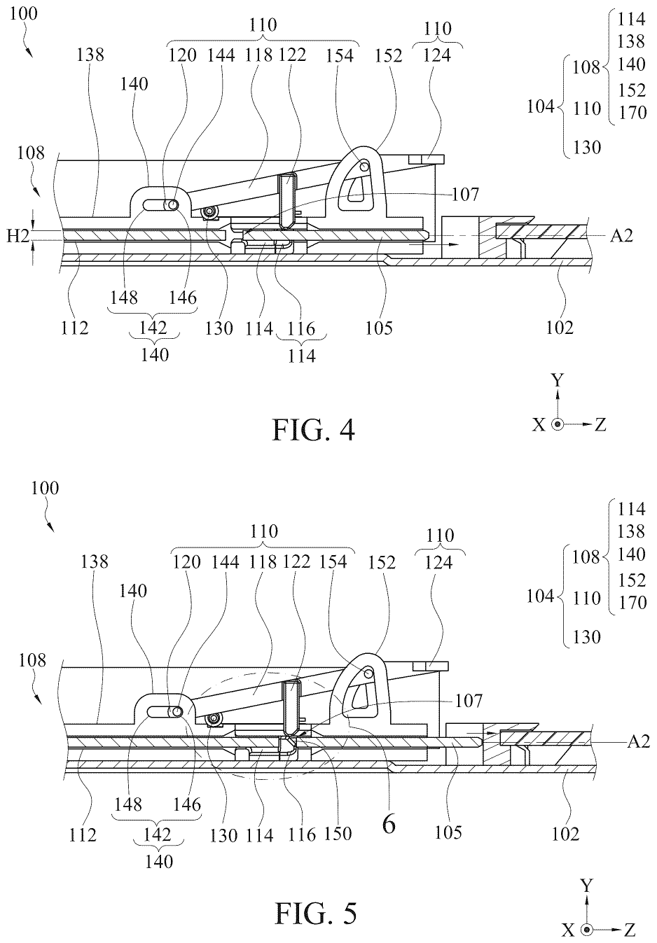

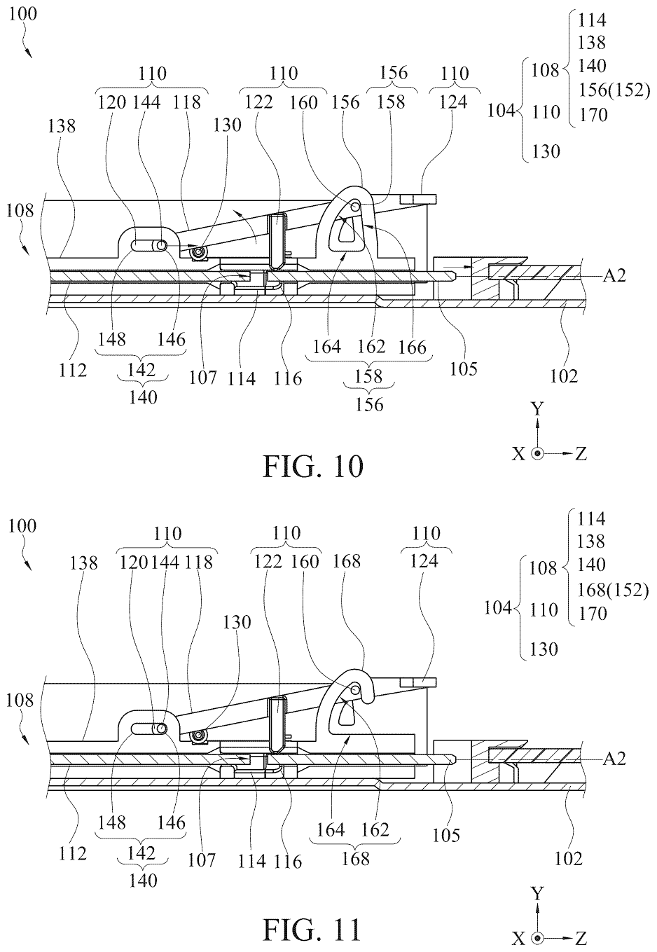

In some embodiments, a server 100 in FIG. 1A, FIG. 2, or FIG. 3 includes a server housing 102 and a guiding device 104. The server housing 102 includes an insertion portion 106. The guiding device 104 includes a base 108 and an unlocking member 110. The base 108 includes a guiding track 112 and a shaft 114. The base 108 is fixed to the server housing 102, and the guiding track 112 is adjacent to the insertion portion 106. The shaft 114 has a fixed portion 116, and the fixed portion 116 has a latch position and a withdrawn position (details are provided below in FIG. 3). The latch position is closer to the insertion portion 106 than the withdrawn position. The unlocking member 110 includes a main body 118, a connecting portion 120, an abutting portion 122, and an operating portion 124. The connecting portion 120, the abutting portion 122, and the operating portion 124 are connected to the main body 118. The unlocking member 110 is movably arranged on the base 108 through the connecting portion 120 to have an initial position (a position of the unlocking member 110 shown in FIG. 1B, FIG. 2, FIG. 4, FIG. 5, or FIG. 10), an unlocking position (a position of the unlocking member 110 shown in FIG. 7), and a removal position (a position of the unlocking member 110 shown in FIG. 9). The operating portion 124 is moved to selectively position the unlocking member 110 at the initial position, the unlocking position, or the removal position. The abutting portion 122 makes the fixed portion 116 at the withdrawn position when the unlocking member 110 is at the unlocking position.

The server 100 may be a tower server, a rack server, a blade server, a cabinet server, or the like. In some examples, the server 100 has a motherboard 101, which is arranged on an assembly surface 103 of the server housing 102. The server 100 may perform data calculation or storage through the motherboard 101. The insertion portion 106 of the server housing 102 may refer to a space in which a plug-in module 105 is installed on the motherboard 101. When the plug-in module 105 is at the insertion portion 106, the plug-in module 105 may be electrically connected to the motherboard 101 to transmit an electronic signal to each other. For example, the motherboard 101 has at least one slot (not shown in the figure), which is adjacent to the insertion portion 106. The insertion portion 106 may be for inserting the plug-in module 105, and is electrically connected to the slot, so that the plug-in module 105 is electrically connected to the motherboard 101. In some examples, a space size of the insertion portion 106 is substantially equal to a volume size of the plug-in module 105. In some examples, the server housing 102 may have a plurality insertion portions 106 and a corresponding quantity of slots to connect to a plurality plug-in modules 105.

Further, as shown in FIG. 1A, FIG. 1B, and FIG. 1C, the base 108 of the guiding device 104 may be fixed on the assembly surface 103 based on the position of the insertion portion 106, so that the guiding track 112 may be adjacent to the insertion portion 106. The plug-in module 105 may be guided by the guiding track 112 to enter the insertion portion 106. Therefore, the guiding track 112 can support the plug-in module 105 to keep a proper distance from the assembly surface 103, and protect the plug-in module 105. In some examples, a height H1 of the guiding track 112 (a length of the guiding track 112 along a Z axis direction in FIG. 2) is slightly greater than a thickness H2 (see FIG. 4 later) of the plug-in module 105, so that the plug-in module 105 may be slidably arranged on the guiding track 112.

The plug-in module 105 may be, for example, but is not limited to, a computing expansion board, a storage expansion board, or expansion hardware based on the Open Compute Project (OCP).

As shown in FIG. 1C and FIG. 3, the shaft 114 may be moved by the plug-in module 105, so that the fixed portion 116 is selectively at the latch position (a position of the shaft 114 in a solid line in FIG. 3) or the withdrawn position (a position of the shaft 114 in a dashed line in FIG. 3). In some examples, the shaft 114 has a fixed section 126 and a movable section 128. The fixed section 126 is connected to the base 108, and the movable section 128 has the fixed portion 116 and is movable at the latch position and the withdrawn position. When the fixed portion 116 is moved, the movable section 128 may be moves to the withdrawn position from the latch position to release the positioning of the plug-in module 105 by the fixed portion 116. Therefore, a position of the fixed portion 116 when the shaft 114 is at the latch position is close to the insertion portion 106 compared with a position of the fixed portion 116 when the shaft 114 is at the withdrawn position.

Further, as shown in FIG. 1B and FIG. 1C, the connecting portion 120 and the operating portion 124 are at two ends of the main body 118 respectively. The unlocking member 110 may perform an unlocking operation relative to the base 108 through the connecting portion 120, so that the unlocking member 110 moves to the initial position, the unlocking position, or the removal position through the unlocking operation. It should be noted that, when the operating portion 124 is not moved, the unlocking member 110 is at the initial position, and the abutting portion 122 is away from the fixed portion 116, so that the fixed portion 116 enters the guiding track 112. In some embodiments, as shown in FIG. 1A, the insertion portion 106 has an insertion axis A1, the guiding track 112 has a guiding axis A2, and the guiding axis A2 is substantially parallel to the insertion axis A1. Therefore, the plug-in module 105 may be guided by the guiding track 112 through the guiding axis A2 (or the insertion axis A1), so that the plug-in module 105 may be inserted into the insertion portion 106 with an allowable error to be electrically connected to the motherboard 101. In some embodiments, as shown in FIG. 1B, a line (the line may refer to an axial direction in a moving direction of the unlocking member 110) between the unlocking position and the removal position is substantially parallel to the insertion axis A1 (or the guiding axis A2). In other words, the connecting portion 120 of the unlocking member 110 may be movably connected to the base 108 based on a movement trajectory of the unlocking operation, so that when the unlocking member 110 moves from the unlocking position to the removal position, the unlocking member 110 is moves to the initial position to be separated from the plug-in module 105 (described later). Therefore, the plug-in module 105 may withdraw from the insertion portion 106 based on the insertion axis A1.

As shown in FIG. 4, the plug-in module 105 is at the guiding track 112, and does not reach the insertion portion 106. Before the operating portion 124 is moved, the unlocking member 110 is at the initial position, and the abutting portion 122 is away from the fixed portion 116. Further, as shown in FIG. 4, when the plug-in module 105 enters the insertion portion 106 based on the guiding axis A2, all or a part of the plug-in module 105 may move (for example, push) the fixed portion 116, so that the fixed portion 116 moves from the latch position to the withdrawn position. It should be noted that, when the plug-in module 105 moves on the guiding track 112, the guiding track 112 may limit the plug-in module 105 in a direction perpendicular to the guiding axis A2 (for example, a Y axis direction in FIG. 4).

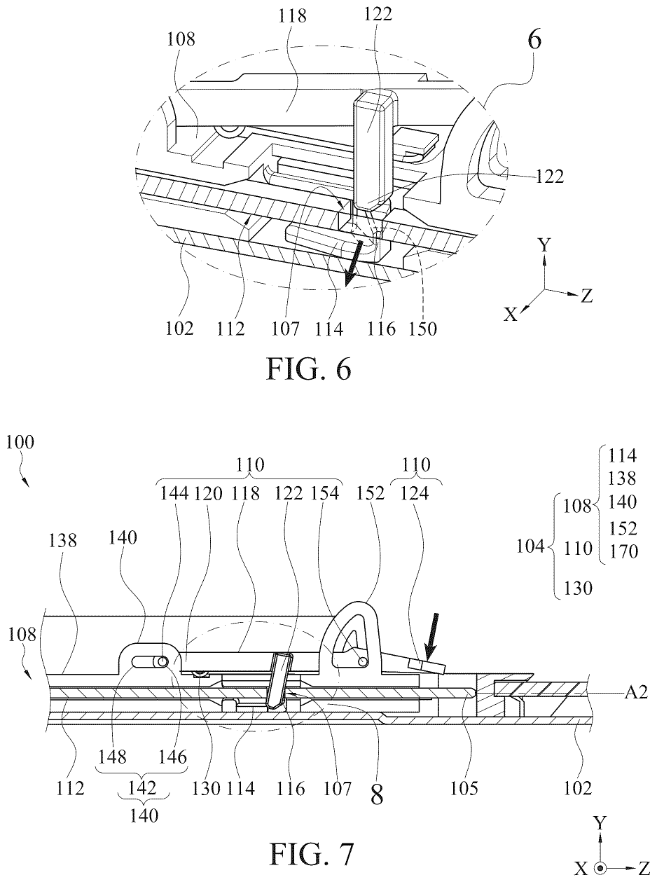

As shown in FIG. 5 and FIG. 6, the plug-in module 105 is at the insertion portion 106, and the unlocking member 110 is not moved. The plug-in module 105 de-moves the fixed portion 116, so that the fixed portion 116 moves from the withdrawn position to the latch position and positions the plug-in module 105. Specifically, when the plug-in module 105 is at the insertion portion 106, a snap portion 107 of the plug-in module 105 is at the latch position, so that the plug-in module 105 no longer pushes against the fixed portion 116. Therefore, the de-moved fixed portion 116 may enter the snap portion 107 to limit the plug-in module 105 at the guiding axis A2 and position the plug-in module 105 at the insertion portion 106. In some examples, the snap portion 107 may be an opening, and a size of the opening of the snap portion 107 is slightly greater than that of the fixed portion 116, so that the fixed portion 116 may enter the snap portion 107.

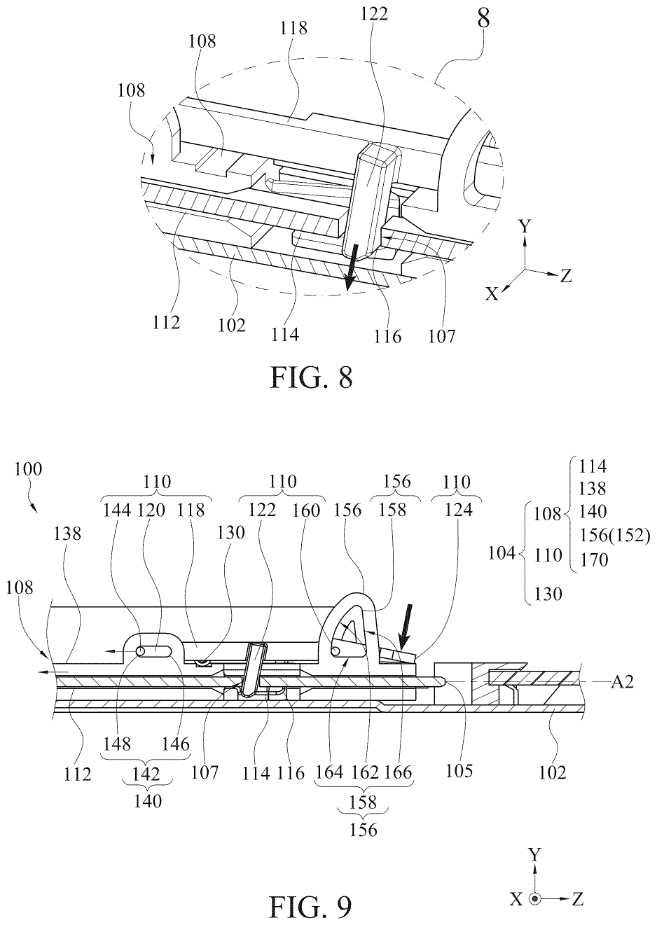

As shown in FIG. 7 and FIG. 8, the plug-in module 105 is at the insertion portion 106. The unlocking member 110 is moved from the initial position to the unlocking position, and the abutting portion 122 may enter the guiding track 112 through the snap portion 107 and move the fixed portion 116, so that the fixed portion 116 is moves to the withdrawn position from the latch position to release the positioning of the plug-in module 105. For example, the operating portion 124 is forced to the unlocking position, so that the main body 118 pivots relative to the base 108 through the connecting portion 120 to move from the initial position to the unlocking position. Therefore, when the fixed portion 116 is moves to the withdrawn position, the fixed portion 116 may release the limit on the guiding axis A2 (or the insertion axis A1), so that the plug-in module 105 is freely movable on the guiding track 112.

As shown in FIG. 9, the unlocking member 110 is moved from the unlocking position to the removal position, the unlocking member 110 moves from the unlocking position to the removal position, and the abutting portion 122 may drive the plug-in module 105 to withdraw from the insertion portion 106 based on the guiding axis A2, so that the snap portion 107 leaves the latch position. For example, the operating portion 124 at the unlocking position is forced to the removal position, and the connecting portion 120 is slidable relative to the base 108, so that the abutting portion 122 slides based on the line between the initial position and the unlocking position. The abutting portion 122 may push the plug-in module 105 at the snap portion 107 to withdraw the plug-in module 105 from the insertion portion 106, and the abutting portion 122 may temporarily limit the plug-in module 105 at the guiding axis A2 (or the insertion axis A1). In some examples, if sides of the plug-in module 105 may all move the fixed portion 116, during movement of the plug-in module 105, even if the abutting portion 122 is away from the fixed portion 116, the fixed portion 116 may still be stopped by the sides of the plug-in module 105 and maintained at the withdrawn position. If the sides of the plug-in module 105 partially move the fixed portion 116 (an adjacent side of the snap portion 107), during movement of the plug-in module 105, the abutting portion 122 is away from the fixed portion 116 and is de-moved. The fixed portion 116 may be moves to the latch position from the withdrawn position, and does not position the plug-in module 105.

As shown in FIG. 10, the guiding device 104 withdraws the plug-in module 105 from the insertion portion 106. The unlocking member 110 is moved from the removal position to the initial position, and the unlocking member 110 is pushed to the initial position from the removal position, so that the abutting portion 122 leaves the snap portion 107 and is away from the guiding track 112. Therefore, the plug-in module 105 is neither limited by the fixed portion 116 at the guiding axis A2 (or the insertion axis A1) nor limited by the abutting portion 122, so that the plug-in module 105 may move out of the guiding track 112 based on the guiding axis A2. When the unlocking member 110 is pushed to the initial position, the main body 118 slides on and pivots relative to the base 108 through the connecting portion 120, so that the unlocking member 110 is moved to the initial position and the abutting portion 122 moves out of the guiding track 112.

In some embodiments, as shown in FIG. 1B, FIG. 1C, and FIG. 3, the guiding device 104 further includes an elastic member 130. Two ends of the elastic member 130 abut against the base 108 and the unlocking member 110 respectively, so that the unlocking member 110 is at the initial position. For example, the elastic member 130 has a fixed section 132, a pivot section 134, and an abutting section 136, and the pivot section 134 is between the fixed section 132 and the abutting section 136. The fixed section 132 is fixed to the base 108, the pivot section 134 is pivoted to the base 108, and the abutting section 136 moves away from the base 108 with the pivot section 134 as the axial center. The abutting section 136 abuts against the main body 118, and the unlocking member 110 may at the initial position by a force applied to the abutting section 136. Therefore, for example, in FIG. 4, the elastic member 130 abuts against the unlocking member 110, so that the unlocking member 110 is at the initial position. For another example, in FIG. 10, the operating portion 124 of the unlocking member 110 is de-moved, and the unlocking member 110 may be pushed to the initial position from the removal position through the elastic member 130. The elastic member 130 may be a torsion spring, a compression spring, or a spring plate.

In some embodiments, as shown in FIG. 1B, FIG. 1C, and FIG. 3, the base 108 further includes a base body 138, and the guiding track 112 is at a side of the base body 138 facing the insertion portion 106. When the fixed portion 116 is at the latch position, the fixed portion 116 is at the guiding track 112. When the fixed portion 116 is at the withdrawn position, the fixed portion 116 is separated from the guiding track 112. For example, before the shaft 114 is moved, the fixed portion 116 is at the latch position, and enters the guiding track 112 in a direction of the insertion portion 106. When the plug-in module 105 moves the fixed portion 116 on the guiding track 112 (for example, the plug-in module 105 pushes the fixed portion 116), the fixed portion 116 may be moved from the latch position to the withdrawn position, so that the fixed portion 116 is moved to the withdrawn position in a direction away from the insertion portion 106 (which may refer to that the fixed portion 116 is still at the guiding track 112 but has released the positioning of the plug-in module 105, or may refer to that the fixed portion 116 leaves the guiding track 112). Correspondingly, when the plug-in module 105 de-moves the fixed portion 116 (for example, the plug-in module 105 is not in contact with the fixed portion 116 or the plug-in module 105 is withdrawn from the guiding track 112), the fixed portion 116 is moved to the latch position. Therefore, when the plug-in module 105 is at the insertion portion 106 and the fixed portion 116 is at the latch position, the fixed portion 116 may position the plug-in module 105, so that the plug-in module 105 may be positioned in the insertion portion 106. In some embodiments, all or a part of the sides of the plug-in module 105 may move the fixed portion 116. For example, if all of the sides of the plug-in module 105 are slidably arranged on the guiding track 112, the fixed portion 116 may be moved at any position of the sides of the plug-in module 105. If only a part of the sides of the plug-in module 105 is slidably arranged on the guiding track 112, the part of the sides of the plug-in module 105 that is slidably arranged on the guiding track 112 moves the fixed portion 116.

In some embodiments, as shown in FIG. 1B, FIG. 1C, and FIG. 2, the base 108 further includes a pivot slider 140. The pivot slider 140 has an elongated slot 142. The connecting portion 120 is a pivot sliding column 144, and the pivot sliding column 144 is at the elongated slot 142, so that the unlocking member 110 is movably arranged on the base 108 through the connecting portion 120 to have the initial position, the unlocking position, and the removal position. For example, as shown in FIG. 7 and FIG. 9, in a process in which the operating portion 124 is moved to make the unlocking member 110 move from the unlocking position to the removal position, the pivot sliding column 144 is limited by a structure of the elongated slot 142, and moves from a first side 146 of the elongated slot 142 to a second side 148. Therefore, in the unlocking operation, the unlocking member 110 is slidable relative to the base body 138 of the base 108. In other words, the movement trajectory of the unlocking member 110 is maintained on the line between the unlocking position and the removal position. Further, as shown in FIG. 10, the operating portion 124 is de-moved, and in a process in which the unlocking member 110 is pushed to the initial position from the removal position, the pivot sliding column 144 moves from the second side 148 to the first side 146, and the unlocking member 110 may pivot relative to the base body 138. In some examples, the unlocking member 110 may be driven by the elastic member 130 to move the pivot sliding column 144.

In some embodiments, as shown in FIG. 5, FIG. 6, FIG. 7, and FIG. 8, the fixed portion 116 has a guiding surface 150. When the unlocking member 110 moves from the initial position to the unlocking position, the unlocking member 110 pushes against the guiding surface 150 to move (swing) the fixed portion 116 to the withdrawn position. In some examples, when the plug-in module 105 moves to the insertion portion 106, the plug-in module 105 may also push against the guiding surface 150 to move the fixed portion 116 to the withdrawn position. It should be noted that, the guiding surface 150 is an inclined surface or a guide angle, and the abutting portion 122 or the plug-in module 105 may reduce a contact area with the guiding surface 150 to reduce a force applied to and a friction force between the unlocking member 110 and the plug-in module 105. The fixed portion 116 can be easily moved to the withdrawn position from the latch position.

In some embodiments, as shown in FIG. 1C and FIG. 2, the base 108 further includes a guiding portion 152. The unlocking member 110 further includes a driven portion 154, and the driven portion 154 is at the guiding portion 152. Further, as shown in FIG. 7 and FIG. 8, when the elastic member 130 pushes the unlocking member 110 to the initial position from the removal position, the driven portion 154 is moved by the guiding portion 152. Therefore, the operating portion 124 is de-moved, the unlocking member 110 may be pushed by the elastic member 130 to pivot relative to the base body 138, and the unlocking member 110 may be pushed to the initial position from the removal position when the guiding portion 152 guides the driven portion 154.

In some examples, as shown in FIG. 9 and FIG. 10, the guiding portion 152 is a guiding ring 156, the guiding ring 156 has a hole 158, the driven portion 154 is a column 160, and the column 160 is in the hole 158. The hole 158 includes a reset guide wall surface 162. When the elastic member 130 pushes the unlocking member 110 to the initial position from the removal position, the column 160 is moved by the reset guide wall surface 162. Therefore, when the unlocking member 110 is pushed by the elastic member 130 to pivot relative to the base body 138, the column 160 may move on the reset guide wall surface 162 until the unlocking member 110 is pushed to the initial position. An opening direction of the reset guide wall surface 162 is opposite to an opening direction of a movement trajectory of the elastic member 130. Therefore, during movement, the column 160 may move along the reset guide wall surface 162.

In some examples, as shown in FIG. 9 and FIG. 10, the hole 158 includes a retraction guiding wall surface 164. When the unlocking member 110 is moved from the unlocking position to the removal position, the column 160 is moved by the retraction guiding wall surface 164. Therefore, when the column 160 is moved by the retraction guiding wall surface 164, the movement trajectory of the unlocking member 110 is maintained on the line between the unlocking position and the removal position. In addition, when the unlocking member 110 moves from the initial position to the snap portion 107, the column 160 may be stopped by the retraction guiding wall surface 164, so that the abutting portion 122 is within the guiding track 112 (not in contact with the guiding track 112) to reduce or avoid a friction force between the abutting portion 122 and the guiding track 112.

In some examples, as shown in FIG. 9 and FIG. 10, the hole 158 includes an unlocking guide wall surface 166. When the unlocking member 110 is moved from the initial position to the unlocking position, the column 160 is moved by the unlocking guide wall surface 166. Therefore, the unlocking member 110 may be guided by an inner side of the unlocking guide wall surface 166 to accurately extend the abutting portion 122 into the snap portion 107 and move the fixed portion 116.

In some embodiments, as shown in FIG. 11, the guiding portion 152 is an arc-shaped guiding member 168. The column 160 is at an inner side of the arc-shaped guiding member 168. When the elastic member 130 pushes the unlocking member 110 to the initial position from the removal position, the column 160 is moved by the inner side of the arc-shaped guiding member 168. Therefore, when the unlocking member 110 is pushed by the elastic member 130 to pivot relative to the base body 138, the column 160 may move in the arc-shaped guiding member 168 until the unlocking member 110 is pushed to the initial position. In some examples, the inner side of the arc-shaped guiding member 168 may refer to a side of a center of a curvature of the arc. A direction of the center of the curvature of the arc-shaped guiding member 168 is opposite to a direction of a center of a curvature of the movement trajectory of the elastic member 130. Therefore, during movement, the column 160 may move along the inner side of the arc-shaped guiding member 168. In some embodiments, the arc-shaped guiding member 168 includes the reset guide wall surface 162 and the retraction guiding wall surface 164. When the unlocking member 110 is moved from the unlocking position to the removal position, the retraction guiding wall surface 164 may guide the column 160 to move from the unlocking position to the removal position. When the unlocking member 110 is moved from the removal position to the initial position, the reset guide wall surface 162 may guide the column 160 to move from the removal position to the initial position.

In some embodiments, as shown in FIG. 1C and FIG. 2, the base 108 further includes a guide groove 170. Two ends of the driven portion 154 are at the guiding portion 152 and the guide groove 170. One end of the driven portion 154 may be guided and limited by the guide groove 170, so that a movement trajectory of the driven portion 154 is limited by the guide groove 170 (a range of the guide groove 170). Another end of the driven portion 154 may be guided by the guiding portion 152. Therefore, the unlocking member 110 may guide the driven portion 154 in both the guiding portion 152 and the guide groove 170, so that the unlocking member 110 moves at the initial position, the unlocking position, or the removal position in a fixed movement trajectory.

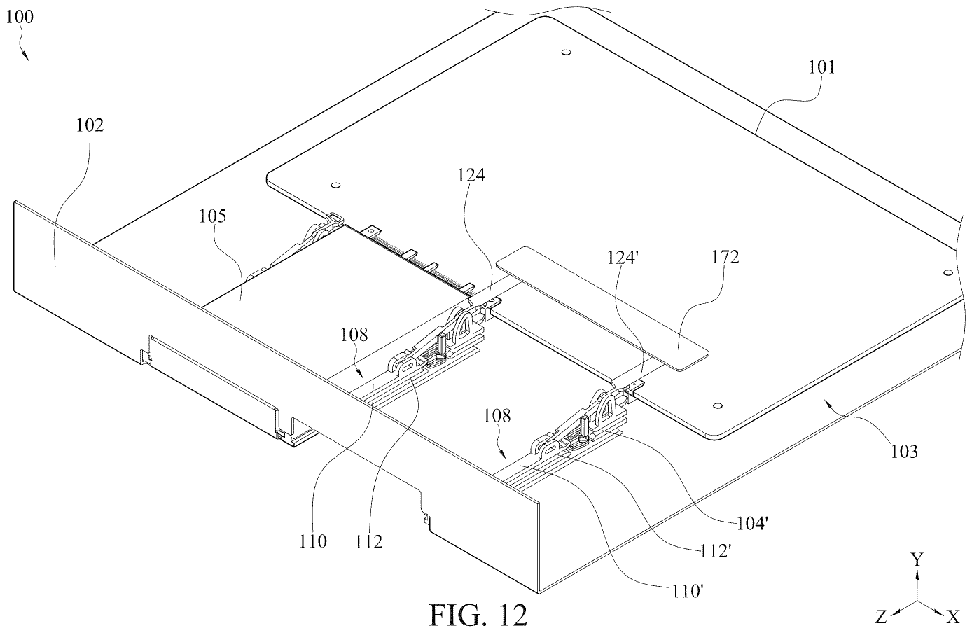

In some embodiments, as shown in FIG. 12, the server 100 includes at least two guiding devices (104 and 104′) and a linkage board 172. The guiding devices (104 and 104′) are arranged in parallel on the assembly surface 103, and guiding tracks (112 and 112′) of the guiding devices (104 and 104′) are at two opposite sides of the insertion portion 106 (the insertion portion 106 may alternatively be a space between the two guiding tracks (112 and 112′)) respectively, so that the two sides of the plug-in module 105 may enter or be withdrawn from the insertion portion 106 through the corresponding guiding tracks (112, 112′). The linkage board 172 is connected to unlocking members (110, 110′) of the guiding devices (104, 104′). One of the unlocking members 110 is moved, and the linkage board 172 moves the other unlocking member 110′. The linkage board 172 is connected to operating portions (124, 124′) of the unlocking members (110, 110′), so that the unlocking members (110, 110′) may move through the linkage board 172.

In some embodiments, for the guiding device 104 shown in FIG. 3, FIG. 11, and FIG. 12, the shaft 114 may alternatively be a spring arm or a swing arm. Therefore, if the shaft 114 is the spring arm (or the swing arm), the fixed portion 116 may be a buckle portion, a hook portion, or a protrusion that is arranged on the spring arm (or the swing arm) and that extends to the insertion portion 106.

In conclusion, in some embodiments, in the server 100, when the plug-in module 105 is to be installed on the server housing 102, the plug-in module 105 may be inserted into the guiding track 112 and withdrawn from the insertion portion 106. The guiding track 112 may limit the plug-in module 105 in a direction perpendicular to the guiding axis A2, so that the plug-in module 105 may enter the insertion portion 106 based on the insertion axis A1. When the plug-in module 105 is at the insertion portion 106, the fixed portion 116 of the shaft 114 is at the latch position to limit the plug-in module 105 in a direction of the insertion axis A1. The unlocking member 110 is moved from the initial position to the unlocking position and the abutting portion 122 may move the fixed portion 116 to the withdrawn position to release the limit of the plug-in module 105 on the insertion axis A1. In response to the unlocking member 110 being moved from the unlocking position to the removal position, the plug-in module 105 may withdraw the insertion portion 106 from the abutting portion 122. In response to the unlocking member 110 being moved from the removal position to the initial position, the abutting portion 122 may leave the guiding track 112, so that the plug-in module 105 may re-enter the insertion portion 106. Therefore, users may withdraw the plug-in module 105 from the server housing 102 by operating the guiding device 104 without touching the plug-in module 105. In this way, the server can prevent operators from inserting/plugging the plug-in module 105 into/from the server housing 102 with an incorrect force and at an incorrect angle.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A server, comprising:
a server housing, comprising an insertion portion; and
a guiding device, comprising:
a base, comprising a guiding track and a shaft, wherein the base is fixed to the server housing and the guiding track is adjacent to the insertion portion, the shaft has a fixed portion, the fixed portion has a latch position and a withdrawn position, and the latch position is closer to the insertion portion than the withdrawn position; and
an unlocking member, comprising a main body, a connecting portion, an abutting portion, and an operating portion, wherein the connecting portion, the abutting portion, and the operating portion are connected to the main body, and the unlocking member is slidably arranged on the base through the connecting portion to have an initial position and an unlocking position, wherein
the operating portion is moved to selectively position the unlocking member at the initial position or the unlocking position, and the abutting portion makes the fixed portion at the withdrawn position when the unlocking member is at the unlocking position.

2. The server according to claim 1, wherein the unlocking member is slidably arranged on the base through the connecting portion to further have a removal position, the unlocking member is selectively positioned at the initial position, the unlocking position, or the removal position by moving the operating portion, the insertion portion has an insertion axis, the guiding track has a guiding axis, the guiding axis is substantially parallel to the insertion axis, and a line between the unlocking position and the removal position is substantially parallel to the guiding axis.

3. The server according to claim 2, wherein the guiding device further comprises an elastic member, and two ends of the elastic member abut against the base and the unlocking member respectively to make the unlocking member at the initial position.

4. The server according to claim 3, wherein the base further comprises a guiding portion, the unlocking member further comprises a driven portion, the driven portion is at the guiding portion, and the driven portion is moved by the guiding portion when the elastic member pushes the unlocking member to the initial position from the removal position.

5. The server according to claim 4, wherein the guiding portion is an arc-shaped guiding member, the driven portion is a column, the column is at an inner side of the arc-shaped guiding member, and the column is moved by the inner side of the arc-shaped guiding member when the elastic member pushes the unlocking member to the initial position from the removal position.

6. The server according to claim 4, wherein the guiding portion is a guiding ring, the guiding ring has a hole, the driven portion is a column, the column is in the hole, the hole comprises a reset guide wall surface, and the column is moved by the reset guide wall surface when the elastic member pushes the unlocking member to the initial position from the removal position.

7. The server according to claim 6, wherein the hole comprises a retraction guiding wall surface, and the column is moved by the retraction guiding wall surface when the unlocking member is moved from the unlocking position to the removal position.

8. The server according to claim 2, wherein the base further comprises a base body, the guiding track is at a side of the base body facing the insertion portion, the fixed portion is at the guiding track when the fixed portion is at the latch position, and the fixed portion is separated from the guiding track when the fixed portion is at the withdrawn position.

9. The server according to claim 2, wherein the base further comprises a pivot slider, the pivot slider has an elongated slot, the connecting portion is a pivot sliding column, and the pivot sliding column is at the elongated slot to make the unlocking member be movably arranged on the base through the connecting portion to have the initial position, the unlocking position, and the removal position.

10. The server according to claim 2, wherein the fixed portion has a guiding surface, and when the unlocking member moves from the initial position to the unlocking position, the unlocking member pushes against the guiding surface to make the fixed portion move to the withdrawn position.

11. A guiding device, comprising:
a base, comprising a base body and a shaft, wherein the shaft is connected to the base body and has a fixed portion, and the fixed portion has a latch position and a withdrawn position; and
an unlocking member, comprising a main body, a connecting portion, an abutting portion, and an operating portion, wherein the connecting portion, the abutting portion, and the operating portion are connected to the main body, and the unlocking member is slidably arranged on the base through the connecting portion to have an initial position and an unlocking position, wherein
the operating portion is moved to selectively position the unlocking member at the initial position or the unlocking position, and the abutting portion makes the fixed portion at the withdrawn position when the unlocking member is at the unlocking position.

12. The guiding device according to claim 11, wherein the unlocking member is slidably arranged on the base through the connecting portion to further have a removal position, the unlocking member is selectively positioned at the initial position, the unlocking position, or the removal position by moving the operating portion, the base comprises a guiding track, the guiding track is at the base body, the guiding track has a guiding axis, and a line between the unlocking position and the removal position is substantially parallel to the guiding axis.

13. The guiding device according to claim 12, wherein the guiding device further comprises an elastic member, and two ends of the elastic member abut against the base and the unlocking member respectively to make the unlocking member at the initial position.

14. The guiding device according to claim 13, wherein the base further comprises a guiding portion, the unlocking member further comprises a driven portion, the driven portion is at the guiding portion, and the driven portion is moved by the guiding portion when the elastic member pushes the unlocking member to the initial position from the removal position.

15. The guiding device according to claim 14, wherein the guiding portion is an arc-shaped guiding member, the driven portion is a column, the column is at an inner side of the arc-shaped guiding member, and the column is moved by the inner side of the arc-shaped guiding member when the elastic member pushes the unlocking member to the initial position from the removal position.

16. The guiding device according to claim 14, wherein the guiding portion is a guiding ring, the guiding ring has a hole, the driven portion is a column, the column is in the hole, the hole comprises a reset guide wall surface, and the column is moved by the reset guide wall surface when the elastic member pushes the unlocking member to the initial position from the removal position.

17. The guiding device according to claim 16, wherein the hole comprises a retraction guiding wall surface, and the column is moved by the retraction guiding wall surface when the unlocking member is moved from the unlocking position to the removal position.

18. The guiding device according to claim 12, wherein the fixed portion is at the guiding track when the fixed portion is at the latch position, and the fixed portion is separated from the guiding track when the fixed portion is at the withdrawn position.

19. The guiding device according to claim 12, wherein the base further comprises a pivot slider, the pivot slider has an elongated slot, the connecting portion is a pivot sliding column, and the pivot sliding column is at the elongated slot to make the unlocking member be movably arranged on the base through the connecting portion to have the initial position, the unlocking position, and the removal position.

20. The guiding device according to claim 12, wherein the fixed portion has a guiding surface, and when the unlocking member moves from the initial position to the unlocking position, the unlocking member pushes against the guiding surface to make the fixed portion move to the withdrawn position.
